(19) United States
(12) Patent Application Publication
(10) Pub. No.: US 2011/0114013 A1
(43) Pub. Date: May 19, 2011

(54) FILM DEPOSITION APPARATUS AND METHOD

(76) Inventors: Kunihiko SUZUKI, Shizuoka (JP); Shinichi Mitani, Shizuoka (JP)

(21) Appl. No.: 12/949,552

(22) Filed: Nov. 18, 2010

(30) Foreign Application Priority Data
Nov. 19, 2009 (JP) 2009-264308

(51) Int. Cl. C23C 16/455; C30B 23/02

(52) U.S. Cl. 117/84; 118/715; 118/724

(57) ABSTRACT

A deposition apparatus 100 comprises a chamber 102; a first gas supply path 140 for supplying a first deposition gas 131 including a silicon source gas to a position directly above an SiC (silicon carbide) wafer 101 placed inside the chamber 102; and a second gas supply path 141 for supplying a second deposition gas 132 including a carbon source gas into the chamber 102. The lower end of the first gas supply path 140 is directly above the wafer 101 inside the chamber 102. The second gas supply path 141 is located at an upper section of the chamber 102. A SiC (silicon carbide) film is deposited on the wafer 101 with the use of the first gas 131 and the second gas 132.

### BACKGROUND OF THE INVENTION

1. Field of the Invention

The present invention relates to a Film Deposition Apparatus and a Method of Film Deposition.

2. Background Art

A single-wafer deposition apparatus is often used to deposit a monocrystalline film, such as a silicon film or the like, on a substrate wafer, thereby forming an epitaxial wafer.

FIG. 3 The deposition apparatus 200 comprises the following components: a film deposition chamber 201; a base 202 on which to place the chamber 201; a gas inlet port 204 for supplying a deposition gas 215 into the chamber 201; a flow straightening vane 230 for feeding the deposition gas 215 uniformly across the top surface of a wafer 203 on which to deposit a monocrystalline; and wafer heating means 205 for heating the wafer 203 for epitaxial growth.

The flow straightening vane 230 is located at an upper section of the chamber 201 and often formed of quartz. The flow straightening vane 230 is provided with multiple through-holes 231 so that the deposition gas 215 fed from the gas inlet port 204 can flow inside the through-holes 231, pass through an inject port 232, and be fed uniformly across the top surface of the wafer 203.

Inside the base 202 is a hollow columnar support 206 that extends upwardly into the chamber 201.

Attached to the upper and lower ends of the hollow columnar support 206 are, respectively, the wafer heating means 205 and an electrode securing unit 207, the latter of which serves as a lower lid for closing the lower end of the columnar support 206. Inside the columnar support 206 are two rod electrodes 208 which extend through the electrode securing unit 207 and are thus secured to the columnar support 206. The two rod electrodes 208 penetrate the upper end of the columnar support 206, extending up to the wafer heating means 205 located inside the chamber 201.

The wafer heating means 205 comprises an electric resistance heater 209 and two electrically-conductive busbars 210 for supporting the heater 209. Each of the busbars 210 is secured to an electrically conductive connector 211 that is connected to the upper end of the columnar support 206, which means that the heater 209 is connected to the columnar support 206 via the connectors 211 and the busbars 210. Further, the two electrodes 208 are each connected to one of the connectors 211. Therefore, electricity can be conducted from the two rod electrodes 208 through the connectors 211 and the busbars 210 to the heater 209 for the purpose of resistively heating the wafer 203. The upper hollow end of the columnar support 206 is also closed by an upper lid 212.

A hollow rotary shaft 221 surrounds the columnar support 206. The rotary shaft 221 is attached to the base 202 such that the rotary shaft 221 can rotate around the columnar support 206 via a bearing not illustrated. The rotation of the rotary shaft 221 is achieved by a motor 222.

A rotary drum 223 is installed on the upper end of the rotary shaft 221 that extends upwardly into the chamber 201. Installed on the top surface of the rotary drum 223 is a susceptor 220 on which to place the wafer 203. Therefore, the susceptor 220 inside the chamber 201 can be rotated above the wafer heating means 205 by the motor 222 rotating the rotary shaft 221 and the rotary drum 223.

Upon the deposition process by the above apparatus 200, the heater 209 of the wafer heating means 205, located below the susceptor 220, first heats the wafer 203 placed on the susceptor 220 while the wafer 203 is being rotated. To deposit an epitaxial film on the wafer 203, the apparatus 200 then supplies the deposition gas 215 through the gas inlet port 204 into the chamber 201. The deposition gas 215 is fed uniformly across the top surface of the wafer 203 by the gas 215 passing through the flow straightening vane 230 and flowing toward the wafer 203.

Japanese Patent Laid-Open No. 2009-21533 discloses a deposition apparatus in which the distance between a flow straightening vane with multiple through-holes and a wafer placed on a susceptor is determined such that deposition gas flow can be laminar over the wafer.

In the above-described conventional deposition apparatus 200, heating by the wafer heating means 205 may cause the temperature of the wafer 203 to become extremely high (e.g., higher than 1,000 degrees Celsius) during vapor-phase deposition for depositing an epitaxial film on the wafer 203.

Depending on the type of an epitaxial film to be deposited on the wafer 203, the wafer 203 may need to be heated even up to 1,500 degrees Celsius or higher.

An example of a material to be used for such an epitaxial film is silicon carbide (SiC), which is a promising material for high-voltage power semiconductor devices. The energy gap of silicon carbide is twice or three times as large as those of conventional semiconductor device materials such as silicon (Si) and gallium arsenide (GaAs), and its breakdown electric field is larger than those of conventional materials by approximately one order of magnitude. To form a SiC epitaxial wafer by growing SiC crystals on a substrate, the substrate needs to be heated up to 1,600 degrees Celsius or thereabout. What is more desirable is to heat the entire surface of the substrate uniformly to 1,700 degrees Celsius or higher.

However, when the heater 209 is used to heat the wafer 203 up to such a high temperature, radiant heat from the heater 209 may heat not only the wafer 203 but other components of the deposition apparatus 200 as well. This unwanted temperature increase is especially noticeable in the inner-walls of the chamber 201 and in the components located closer to the wafer 203 and to the heater 209.

When the deposition gas 215 flows into the chamber 201 and comes into contact with those excessively heated components that require no heating, the gas 215 may thermally decompose itself as if the gas 215 came into contact with the heated wafer 203.

When a SiC epitaxial film is formed on a substrate, it is often the case that the deposition gas 215 comprises silane (SiH₄, used as a silicon source), propane (C₃H₈, used as a carbon source), and a hydrogen gas (used as a carrier gas). After the wafer 203 is heated, the deposition gas 215 is fed through the gas inlet port 204 into the chamber 201 as stated above. The gas 215 then reaches the top surface of the wafer 203 where the gas 215 thermally decomposes itself to form a SiC epitaxial film.

However, when the deposition gas 215 comprises the above substances and is thus highly reactive, the gas 215 may thermally decompose itself even if the gas 215 comes into contact with excessively heated components inside the chamber 201 other than the wafer 203. As a result, crystalline particles may be attached to those components due to the decomposition of the deposition gas 215.

What the above implies is that part of the deposition gas 215 is reduced to by-products without being used for deposition of an epitaxial film on the wafer 203.

Such by-products may come off eventually and accumulate as dust particles inside the chamber 201 if the deposition apparatus 200 is used over and over, which involves repetitions of temperature increases and decreases inside the chamber 201. Those dust particles may contaminate films to be deposited on substrates during subsequent vapor-phase epitaxial processes and can be a factor that lowers product quality.

Thus, the conventional film deposition apparatus 200 requires frequent maintenance for removing dust particles, which means that the operating rate of the apparatus 200 cannot be increased beyond a particular point.

As above, problems with the conventional deposition apparatus 200 include; inefficient use of the deposition gas 215, concern about the quality of epitaxial films to be deposited on wafers, and operating rate decreases due to frequent maintenance. These problems manifest themselves especially in the case of SiC film deposition in which the deposition gas is highly reactive by itself and a wafer needs to be heated to a very high temperature (e.g., to 1,500 degrees Celsius or higher).

Accordingly, there is a growing demand for a new apparatus or method for film deposition that prevents deposition gas from coming into contact with other components inside a chamber than a heated wafer so that the gas cannot be wasted due to unnecessary thermal decomposition. In other words, what is needed is a new film deposition apparatus or method that allows efficient use of deposition gas in depositing an epitaxial film on a wafer and is capable of forming high-quality epitaxial films each of a uniform thickness.

Such demands are greater in the case of SiC film deposition in which a wafer needs to be heated to a very high temperature.

The present invention has been contrived to address the above issues associated with conventional film deposition apparatuses and methods. One of the objects of the invention is to provide an apparatus and a method for film deposition that allows efficient use of deposition gas by suppressing its unnecessary thermal decomposition during film deposition that involves wafer heating and that is also capable of forming high-quality films each of a uniform thickness.

Another object of the invention is to provide an apparatus and a method for film deposition that bring about the same advantages as above, even in the case of SiC film deposition in which the substrate is heated to a very high temperature.

### SUMMARY OF THE INVENTION

The present invention has been contrived to address the above issues associated with conventional film deposition apparatuses and methods. In one embodiment of this invention a film deposition apparatus is provided in which different deposition source gasses can be supplied through different gas supply paths into a chamber when a SiC film is deposited on a wafer. The deposition apparatus is also designed so that a highly reactive silicon source gas can be fed to a location directly above the wafer thereby allowing a chemical reaction to take place between the silicon source gas and another source gas. This embodiment allows the deposition apparatus to prevent deposition gas from coming into contact with components inside the chamber other than the wafer so that the gas cannot be wasted due to unnecessary thermal decomposition.

In another aspect of this invention, a double-pipe apparatus structure with an inner and outer pipe allowing one gas to be used as a coolant gas for the other.

According to another aspect of the invention, a film deposition method is provided, in which a silicon source gas and a carbon source gas can be supplied through different gas supply paths into a chamber when a SiC film is deposited on a wafer. Under this method, the highly reactive silicon source gas can be directly fed to a location immediately above the wafer, and the chemical reaction takes place between the silicon source gas and the carbon source gas via the carbon source gas being supplied from another gas supply path onto the wafer. This method allows high quality SiC epitaxial films of uniform thickness to be produced.

### BRIEF DESCRIPTION OF THE DRAWINGS

FIG. 1 is a schematic cross section of a film deposition apparatus according to an embodiment of the invention.

FIG. 2 is a cross section of the double-pipe structure as described above.

FIG. 3 is a schematic cross section of a film deposition apparatus.

### DETAILED DESCRIPTION OF THE EMBODIMENTS

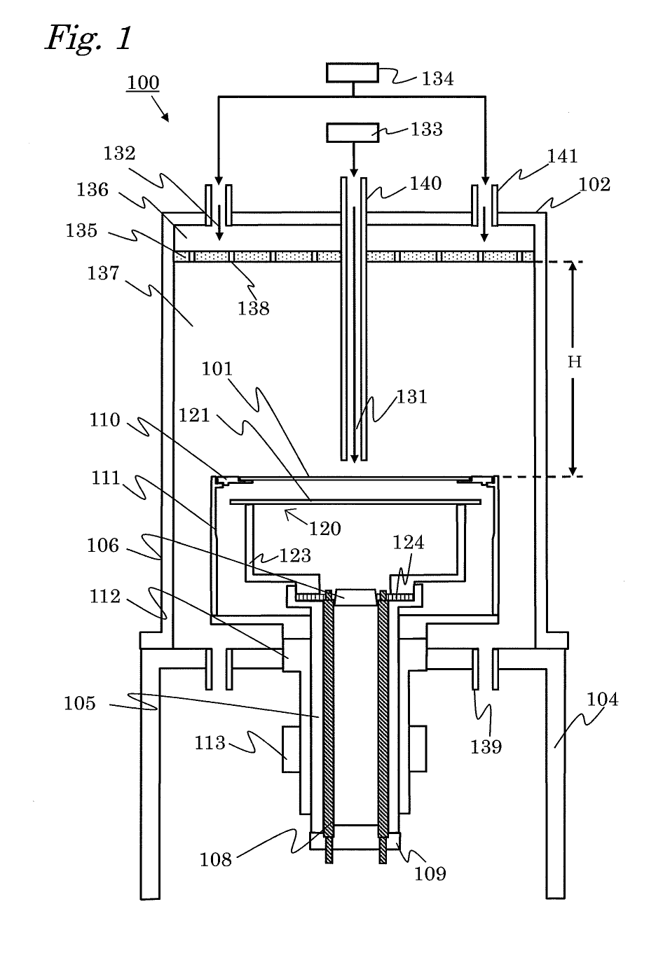

FIG. 1 is a schematic cross section of a film deposition apparatus 100 according to an embodiment of the invention. In this preferred embodiment, the deposition apparatus 100 is designed to deposit a SiC (silicon carbide) epitaxial film on the top surface of a wafer 101. The wafer 101 is formed of SiC, for example. Of course, it is also possible to use other wafers formed of different materials if so required. Examples of alternative wafers include a Si wafer, other insulative wafers such as a SiO₂ (quartz) wafer and the like. Further examples include semi-insulative wafers such as a high-resistance gallium arsenide (GaAs) wafer and the like.

The deposition apparatus 100 includes a chamber 102, inside which, a SiC epitaxial film is deposited on the SiC wafer 101.

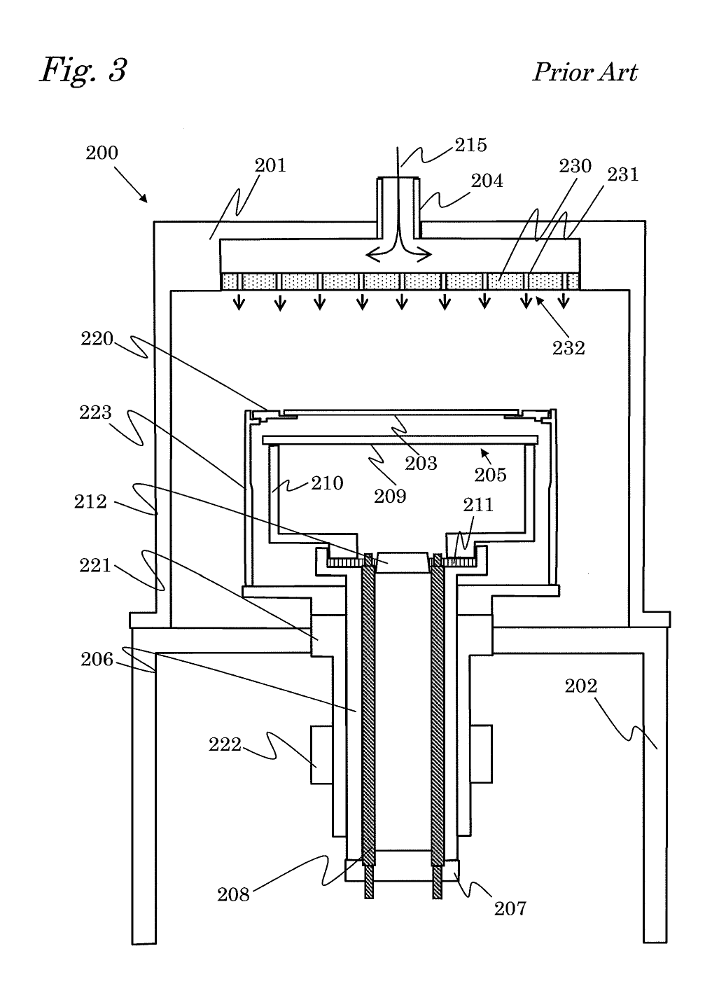

As stated earlier, the conventional deposition apparatus 200 of FIG. 3 uses as the deposition gas 215 a mixed gas comprising silane (SiH₄, used as a silicon source), propane (C₃H₈, used as a carbon source), and a hydrogen gas (used as a carrier gas), and the single gas inlet port 204 is used to feed the deposition gas 215 into the chamber 201, thereby forming a SiC epitaxial film on the wafer 203.

In contrast, the deposition apparatus 100 of the present embodiment is designed to use different gas supply paths to supply two different gases into the chamber 102 for the purpose of forming a SiC epitaxial film on the wafer 101. As will be discussed more in detail, the more reactive of the two (i.e., the gas that includes a more reactive source gas) is fed to a location immediately above the wafer 101 so that chemical reactions will take place primarily between source gases right above the wafer 101.

As illustrated in FIG. 1, an upper portion of the chamber 102 is thus provided with two types of gas supply paths: a first gas supply path 140 and second gas supply paths 141.

Further, the deposition apparatus 100 uses two types of deposition gases: a first deposition gas 131 that includes a silicon (Si) source gas and a second deposition gas 132 that includes a carbon (C) source gas.

In the present embodiment, the first deposition gas 131 is fed through the first gas supply path 140 into the chamber 102, and the second deposition gas 132 is fed through the second gas supply paths 141 into the chamber 102.

As the silicon source gas, the first deposition gas 131 includes a silane source gas; however, the first gas 131 may also include a dichlorosilane source gas or a trichlorosilane source gas. Also, as the carbon source gas, the second deposition gas 132 includes a propane source gas; however, the second gas 132 may also include an acetylene source gas. Note that each of the first deposition gas 131 and the second deposition gas 132 also includes a hydrogen gas as a carrier gas.

The first deposition gas 131 including silane is generated by mixing a silane gas supplied from a silane supply source 133 with a hydrogen gas supplied from a hydrogen gas supply source not illustrated (e.g., a hydrogen tank). The generated first gas 131 is fed into the chamber 102 through the first gas supply path 140.

The second deposition gas 132 including propane is generated by mixing a propane gas supplied from a propane gas supply source 134 with a hydrogen gas supplied from the hydrogen gas supply source. The generated second gas 132 is fed into the chamber 102 through the second gas supply paths 141.

The chamber 102 of the deposition apparatus 100 houses a flow straightening vane 135. As illustrated in FIG. 1, the flow straightening vane 135 sections the entire inner area of the chamber 102 into two zones: a flow buffer zone 136 and a deposition zone 137 in which an epitaxial film is deposited on the wafer 101.

As also illustrated in FIG. 1, the flow straightening vane 135 includes multiple through-holes 138 that vertically extend through the vane 135. The through-holes 138 are arranged across the flow straightening vane 135 at particular intervals.

After flowing through the second gas supply paths 141, the second deposition gas 132 first enters the flow buffer zone 136. The second gas 132 then flows through the through-holes 138 of the flow straightening vane 135, whereby the second gas 132 can be supplied uniformly across the deposition zone 137. After entering the deposition zone 137, the second gas 132 flows downward toward the wafer 101.

In the present embodiment, the distance H between the flow straightening vane 135 and the wafer 101 is determined such that the flow of the second deposition gas 132 can be laminar over the wafer 101.

After the second deposition gas 132 passes through the through-holes 138 of the flow straightening vane 135, its flow is made laminar. The second gas 132 then flows downward toward the wafer 101, forming a vertical laminar flow. As the second gas 132 approaches the wafer 101, the wafer 101 rotating at high speed attracts the second gas 132. Attracted by the rotating wafer 101, the second gas 132 collides with the wafer 101 and then streams over the top surface of the wafer 101 in the form of a horizontal laminar flow, without causing turbulent flows. By determining the distance H such that the flow of the second gas 132 can be laminar over the wafer 101 as above, it is possible to form a uniformly thick, high-quality epitaxial film on the wafer 101.

It is preferred that the distance H be equal to or less than five times the diameter of a ring-shaped susceptor 110, later described, on which to place the wafer 101. By thus determining the distance H, the flow of the second deposition gas 132 over the wafer 101 can easily be made laminar.

As illustrated in FIG. 1, the first gas supply path 140 through which the first deposition gas 131 flows extends downwardly through the flow straightening vane 135 up to a location immediately above the wafer 101. As also illustrated, the portion of the first gas supply path 140 that is housed by the chamber 102 is pipe-shaped.

It is preferred that the distance between the lower end of the first gas supply path 140 and the wafer 101 be twice to ten times (preferably three times) the thickness of a SiC epitaxial film to be deposited on the wafer 101. This distance is determined based on vapor-phase temperatures around the wafer 101 during wafer heating and the rotational speed of the wafer 101, so that the flows of the deposition gases 131 and 132 cannot be disturbed.

The first gas supply path 140 is installed into the chamber 102 such that the distance between the lower end of the first gas supply path 140 and the wafer 101 can be changed to a desired value. In other words, the first gas supply path 140 is vertically movable so that the position of its lower end can be changed.

It is to be noted that the pipe portion of the first gas supply path 140 that is housed by the chamber 102 is formed of a SiC-coated carbon material.

The first deposition gas 131 passing through the first gas supply path 140 is not supplied to the flow buffer zone 136 but supplied directly to a location immediately above the wafer 101 in the deposition zone 137.

Thus, in the buffer zone 136, the first deposition gas 131 and the second deposition gas 132 almost never come into contact with each other, nor do they react with each other.

Since the lower end of the first gas supply path 140 extends up to a location immediately above the wafer 101 in the deposition zone 137, it is immediately above the wafer 101 where the first gas 131 and the second gas 132 are mixed for the first time. In other words, the two different deposition gasses 131 and 132 can be supplied to a location immediately above the wafer 101 without being mixed until the gasses 131 and 132 reach that location.

By the time the first gas 131 is discharged from the first gas supply path 140, the second gas 132 will be streaming over the top surface of the wafer 101 in the form of a laminar flow. After discharged from the first gas supply path 140, the first gas 131 streams in this laminar flow and is mixed with the second gas 132 right above the wafer 101. The mixing of the two gasses 131 and 132, causes chemical reactions, which lead to the formation of a SiC epitaxial film on the wafer 101.

Unreacted portions of the first and second gasses 131 and 132 and generated gasses resulting from the reactions are discharged out of the chamber 102 through exhaust ports 139 that are located at a bottom section of the chamber 102.

It should be noted that the deposition apparatus 100 of the present embodiment can also use a gas including a carbon source gas as the first deposition gas 131 and a gas including a silicon source gas as the second deposition gas 132.

However, silicon source gasses such as silane, dichlorosilane, and trichlorosilane are highly reactive whereas carbon source gasses such as propane and the like are more stable than silicon source gasses. Therefore, as in the above-described embodiment, it is preferred that the first deposition gas 131 to be supplied through the first gas supply path 140 be a gas including a silicon (Si) source gas and that the second deposition gas 132 to be supplied through the second gas supply paths 141 be a gas including a carbon (C) source gas.

More specifically, silane and other silicon source gasses may thermally decompose by themselves when heated. Propane and other carbon source gasses, on the other hand, are relatively stable and less likely to decompose by themselves even if they touch high-temperature components inside the chamber 102. Accordingly, as in the above-described embodiment, the use of propane (carbon source gas) for the second deposition gas 132 is more suitable for forming a vertical gas flow above the heated wafer 101 in the deposition zone 137.

The deposition apparatus 100 further includes a base 104 on which to place the chamber 102. Inside the base 104 is a non-electrically-conductive, hollow, columnar support 105 that extends upwardly into the chamber 102.

A hollow rotary drum 111 is installed in the deposition zone 137 inside the chamber 102, and the ring-shaped susceptor 110 on which to place the wafer 101 is provided on the top surface of the rotary drum 111. The rotary drum 111 is supported by a hollow rotary shaft 112 and houses the upper portion of the columnar support 105 that protrudes from the base 104.

The rotary shaft 112 is attached to the base 104 such that the rotary shaft 112 can rotate around the columnar support 105 via a bearing not illustrated. The rotation of the rotary shaft 112 is achieved by a motor 113. When the motor 113 causes the rotary shaft 112 to rotate, the rotary drum 111 attached to the rotary shaft 112 also starts to rotate, and so does the susceptor 110 attached to the rotary drum 111.

Wafer heating means 120 is provided above the columnar support 105 so that the wafer 101 can be heated during vapor-phase deposition over the wafer 101. The upper hollow end of the columnar support 105 is closed by an upper lid 106.

Although not illustrated, a radiation thermometer is provided at an upper section inside the chamber 102 to measure the surface temperature of the wafer 101 while the wafer 101 is being heated. It is preferred that the chamber 102 and the flow straightening vane 135 be formed of quartz because, as known in the art, the use of quartz prevents the chamber 102 and the flow straightening vane 135 from affecting the temperature measurement by the radiation thermometer. After the temperature measurement, the data is sent to a control device not illustrated.

When the temperature of the wafer 101 reaches or exceeds a particular value, the control device regulates the above-mentioned hydrogen gas supply source (not illustrated) to control the supply of hydrogen gas to the chamber 102. The control device also regulates the output of the heater 121, described later.

As illustrated in FIG. 1, the upper portion of the columnar support 105 which is located above the main cylindrical structure of the support 105 can be shaped to have a ring or flange structure whose diameter is greater than the outer diameter of the main cylindrical structure of the support 105. The ring or flange structure can also be provided with an upwardly extending rim around its outer circumference, as is also illustrated in FIG. 1. Shaping the upper portion of the columnar support 105 as above allows reliable attachment of the wafer heating means 120, described later in detail.

Installed inside the hollow columnar support 105 are two electrode assemblies. Each of the electrode assemblies includes a rod electrode 108 formed of metallic molybdenum (Mo) and also includes an electrically-conductive connector 124, fixed to the upper end of the rod electrode 108, for supporting an electrically-conductive busbar 123.

The connectors 124 of the electrode assemblies are shaped such that the connectors 124 extend toward the outer circumference of the columnar support 105 from the upper ends of the rod electrodes 108. Thus, the electrode assemblies, each comprising a connector 124 and a rod electrode 108, are L-shaped. Each of the connectors 124 is also formed of metallic molybdenum, meaning that the entire electrode assemblies are formed of metallic molybdenum.

An electrode securing unit 109 is attached to the lower end of the columnar support 105. The electrode securing unit 109 secures the rod electrodes 108, which extend upwardly through the electrode securing unit 109. The electrode securing unit 109 also serves as a lower lid for closing the lower end of the hollow columnar support 105.

As stated above, the deposition apparatus 100 includes the wafer heating means 120 to heat the wafer 101 during vapor-phase deposition, thereby forming an epitaxial film on the top surface of the wafer 101.

The wafer heating means 120 comprises the following components: the heater 121 for heating the wafer 101; and the two arm-like busbars 123 for supporting the heater 121. The lower ends of the busbars 123 are attached to the connectors 124 via bolts or the like.

The heater 121 is formed of silicon carbide (SiC), and the two busbars 123 for supporting the heater 121 are electrically conductive and formed of a SiC-coated carbon material, for example. Since both the connectors 124 and the rod electrodes 108 are formed of molybdenum as stated above, electricity can be conducted from the electrode assemblies through the busbars 123 to the heater 121.

The lower surfaces of the connectors 124 are at least partially in contact with the top surface of the upper portion of the columnar support 105, which portion protrudes from the main cylindrical structure of the support 105. Further, either each of the busbars 123 or each of the connectors 124 is in contact with the upwardly extending rim of the upper portion of the columnar support 105 in at least two places.

Since the electrode securing unit 109 is attached to the lower end of the columnar support 105, that is, located outside the chamber 102, it is less exposed to high temperatures. Thus, the material for the electrode securing unit 109 can be selected from among a relatively wide range of materials. It is preferred to use a material which is moderate in thermal resistance and flexibility. An example of such a material is resin, and a fluorine resin is particularly preferred because it is less subject to degradation under the above temperature environment.

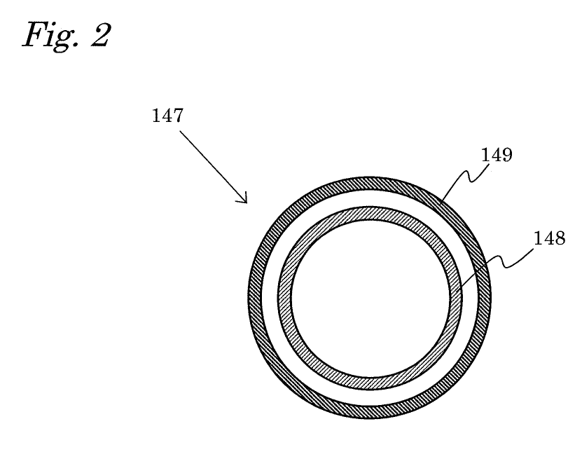

As illustrated in FIG. 2, the pipe portion of the first gas supply path 140 which is housed by the chamber 102 can also have a double-pipe structure. FIG. 2 is a cross section of this double-pipe structure of the first gas supply path 140.

As already stated, the lower end of the first gas supply path 140 of the deposition apparatus 100 extends to a location immediately above the wafer 101, and the portion of the first gas supply path 140 that is housed by the chamber 102 is pipe-shaped. Further, the first deposition gas 131, or a gas including silane as a silicon source gas and a hydrogen gas as a carrier gas, is fed through the first gas supply path 140 to that location above the wafer 101.

As illustrated in FIG. 2, the pipe portion, denoted by reference numeral 147 in FIG. 2, of the first gas supply path 140 can have a double-pipe structure having an inner pipe 148 and an outer pipe 149, so that different gasses can be supplied through the inner pipe 148 and the outer pipe 149. For example, a gas including silane (silicon source gas) and a hydrogen gas (carrier gas) can be supplied into the inner pipe 148, and a hydrogen gas can be supplied into the outer pipe 149.

Such a double-pipe structure allows the first gas supply path 140 to feed two different gasses onto the wafer 101. In addition, such a double-pipe structure allows a gas flowing through the outer pipe 149 to cool the inner pipe 148 as well as the outer pipe 149, whereby a gas flowing through the inner pipe 148 (e.g., a gas including silane) can also be cooled. Accordingly, it is possible to prevent a highly reactive gas such as silane or the like from thermally decompose inside the pipe portion 147 of the first gas supply path 140 due to a temperature increase in the deposition zone 137 of the chamber 102.

When, as in the above example, a gas including silane and a hydrogen gas is to be supplied into the inner pipe 148 and a hydrogen gas is to be supplied into the outer pipe 149, it is preferred to adjust the concentration of the hydrogen gas to be supplied into the inner pipe 148. Specifically, if the double-pipe structure of FIG. 2 is to be adopted, it is preferred to make the concentration of the hydrogen gas to be supplied into the inner pipe 148 smaller than the concentration of a hydrogen gas to be included in the first deposition gas 131 when the first gas supply path 140 has a single-pipe structure. Because, in the case of the double-pipe structure, a hydrogen gas is also supplied through the outer pipe 149 toward the wafer 101, this hydrogen supply amount needs to be considered when adjusting the concentration of the hydrogen gas to be supplied into the inner pipe 148.

Further, while the deposition apparatus 100 of the above embodiment has the single first gas supply path 140 which extends to a location immediately above the wafer 101, it is also possible for the apparatus 100 to have multiple gas supply paths of such a pipe structure.

In that case, different gasses can be supplied into different gas supply paths. For example, one of the gas supply paths can be used for feeding a silicon source gas such as silane or the like onto the wafer 101, and the rest of the supply paths can be used for feeding dopant gases supplied from dopant gas supply sources (not illustrated) as well as a hydrogen gas (carrier gas) onto the wafer 101. The supply of such dopant gasses allows formation of an impurity-added SiC epitaxial film on the wafer 101.

Examples of dopant gasses include those used for forming p-type SiC films such as a TMA (trimethylaluminum) gas and a TMI (trimethylindium) gas. Of course, other types of dopant gasses can also be used.

When multiple gas supply paths structurally similar to the first gas supply path 140 are used as above for supplying a silicon source gas and dopant gases, it is possible to sequentially deposit different SiC epitaxial films on the wafer 101 and thereby to obtain a multi-layered film.

When the chamber 102 is to be provided with multiple gas supply paths structurally similar to the first gas supply path 140 and one of the supply paths is used for supplying a TMI gas, it is preferred that the TMI-gas supply path have the double-pipe structure of FIG. 2 because the TMI gas is a highly reactive gas which may decompose even at room temperature.

In that case, the TMI gas can be supplied into the inner pipe of the TMI-gas supply path, and a hydrogen gas can be supplied into its outer pipe, so that the hydrogen gas can cool the TMI gas to prevent decomposition of the TMI gas. As above, when highly reactive gasses are supplied through gas supply paths, it is preferred that those supply paths have a double-pipe structure.

Described next with reference to FIG. 1 is a method for film deposition according to the present embodiment.

Deposition of a SiC epitaxial film on the SiC wafer 101 takes the following steps.

The wafer 101 is first loaded into the chamber 102. The wafer 101 is placed on the susceptor 110, and the rotary drum 111 then starts rotation to rotate the wafer 101 at 50 rpm or thereabout.

Next, the heater 121 of the wafer heating means 120 is activated to heat the wafer 101 gradually up to, for example, 1,600 degrees Celsius, a film deposition temperature. After the above-mentioned radiation thermometer (not illustrated) registers 1,600 degrees Celsius, meaning that the temperature of the wafer 101 has reached that value, then, the rotational speed of the wafer 101 is increased gradually.

After the wafer heating, the second deposition gas 132 that includes a propane gas supplied from the propane gas supply source 134 and a hydrogen gas supplied from the above-mentioned hydrogen gas supply source (not illustrated) is supplied into the second gas supply paths 141. After passing through the second gas supply paths 141, the second gas 132 flows downward through the flow straightening vane 135 toward the top surface of the wafer 101 which lies in the deposition zone 137.

As stated above, the distance H between the flow straightening vane 135 and the wafer 101 is such that the flow of the second gas 132 can be laminar over the wafer 101.

After the second gas 132 passes through the through-holes 138 of the flow straightening vane 135, its flow is made laminar. The second gas 132 then flows downward toward the wafer 101, forming a vertical laminar flow.

In the meantime, the first deposition gas 131 that includes a silane gas supplied from the silane supply source 133 and a hydrogen gas supplied from the hydrogen gas supply source (not illustrated) is fed into the first gas supply path 140.

Since the first gas supply path 140 extends downwardly up to a location immediately above the wafer 101, it is right above the wafer 101 where the first gas 131 is mixed with the second gas 132 for the first time. In other words, the two different deposition gasses 131 and 132 can be supplied to a location immediately above the wafer 101 without being mixed until the gasses 131 and 132 reach that location.

By the time the first gas 131 is discharged from the first gas supply path 140, the second gas 132 will be streaming over the top surface of the wafer 101 in the form of a laminar flow. After being discharged from the first gas supply path 140, the first gas 131 streams in this laminar flow and is mixed with the second gas 132 right above the wafer 101. Mixing the two gasses 131 and 132 causes chemical reactions, which lead to the formation of a SiC epitaxial film on the wafer 101.

After an epitaxial film of a particular thickness is deposited on the wafer 101, the supply of the first and second deposition gases 131 and 132 is stopped. The supply of the hydrogen gas (carrier gas) can also be stopped at the same time; alternatively, it can also be stopped after the temperature of the wafer 101, as measured by the radiation thermometer, becomes lower than a particular value.

Finally, the wafer 101 is transferred out of the chamber 102 after the temperature of the wafer 101 is reduced to a particular value.

As above, during formation of a SiC epitaxial film on the SiC wafer 101, the deposition gases 131 and 132 can be used efficiently by suppressing unnecessary thermal decomposition of their deposition source gasses. Accordingly, it is possible to form high-quality SiC epitaxial films each of a uniform thickness.

The features and advantages of the present invention may be summarized as follows:

According to a first aspect of the invention, a film deposition apparatus is provided in which different deposition source gasses can be supplied through different gas supply paths into a chamber when a SiC film is deposited on a wafer. The deposition apparatus is also designed so that a highly reactive silicon source gas can be fed directly to a location immediately above the wafer thereby allowing a chemical reaction to take place between the silicon source gas and another source gas, the latter gas being supplied from another gas supply path onto the wafer.

Therefore, the deposition apparatus is capable of efficiently using deposition gases by suppressing unnecessary thermal decomposition of their deposition source gasses during formation of a SiC epitaxial film on a wafer. The deposition apparatus is also capable of forming high-quality SiC epitaxial films each of a uniform thickness.

According to a second aspect of the invention, a film deposition method is provided, in which a silicon source gas and a carbon source gas can be supplied through different gas supply paths into a chamber when a SiC film is deposited on a wafer. Under this method, the highly reactive silicon source gas can be directly fed to a location immediately above the wafer, and chemical reactions take place between the silicon source gas and the carbon source gas by the carbon source gas being supplied from another gas supply path onto the wafer.

Therefore, the deposition method allows efficient use of deposition gases by suppressing unnecessary thermal decomposition of their deposition source gasses during formation of a SiC epitaxial film on a wafer. The deposition method also allows formation of high-quality SiC epitaxial films each of a uniform thickness.

Obviously many modifications and variations of apparatus and/or methods are possible in light of the present invention. It is therefore to be understood that within the scope of the appended claims the invention may be practiced otherwise than as specifically described.

The entire disclosure of a Japanese Patent Application No. 2009-264308, filed on Nov. 19, 2009 including specification, claims, drawings and summary, on which the Convention priority of the present application is based, are incorporated herein.

What is claimed is:

1. A film deposition apparatus comprising:
A film deposition chamber;
A first gas supply path for supplying a first deposition gas including a silicon source gas into the chamber; and
A second gas supply path for supplying a second deposition gas including a carbon source gas into the chamber,
wherein the apparatus deposits a silicon carbide (SiC) film on a substrate placed inside the chamber by using the first gas and the second gas, and
wherein the end of the first gas supply path is directly above the substrate.

2. The film deposition apparatus of claim 1, wherein the second gas supply path is located at an upper section of the chamber so that reactions can take place between the first gas and the second gas over the substrate by the second gas flowing downward toward the substrate.

3. The film deposition apparatus of claim 1, wherein the portion of the first gas supply path that is housed by the chamber has a double-pipe structure having an inner pipe and an outer pipe, wherein the first gas is introduced into the inner pipe, and wherein a gas different from the first gas is introduced into the outer pipe.

4. The film deposition apparatus of claim 3, wherein the gas different from the first gas is used as a coolant gas for cooling the first gas.

5. The film deposition apparatus of claim 1, further comprising at least one extra gas supply path, wherein the end of the extra gas supply path is directly above the substrate.

6. The film deposition apparatus of claim 5, wherein a dopant gas is supplied through the extra gas supply path into the chamber.

7. A film deposition method comprising the steps of:
Positioning a substrate inside a chamber;
supplying a gas including a silicon source gas toward the substrate from a first gas supply path whose end is directly above the substrate; and
supplying a gas including a carbon source gas toward the substrate from a second gas supply path located at an upper section of the chamber, thereby forming a silicon carbide (SiC) film on the substrate.

8. The film deposition method of claim 7, wherein the first gas supply path has a double-pipe structure having an inner pipe and an outer pipe, wherein the gas including the silicon source gas is supplied through the inner pipe, and wherein a coolant gas for cooling the gas including the silicon source gas is supplied through the outer pipe.

9. The film deposition method of claim 7, wherein a dopant gas is supplied into the chamber through an extra gas supply path whose end is directly above the substrate, thereby forming an impurity-added silicon carbide (SiC) film on the substrate.

10. The film deposition method of claim 7, wherein different dopant gasses are supplied into the chamber through different extra gas supply paths, an end of each of which is directly above the substrate, and wherein different silicon carbide (SiC) films are sequentially deposited on the substrate to obtain a multi-layered film.
